(19) United States
(12) Patent Application Publication
(10) Pub. No.: US 2017/0241017 A1
(43) Pub. Date: Aug. 24, 2017

(54) SUBSTRATE TREATING APPARATUS AND SUBSTRATE TREATING METHOD

(71) Applicant: SCREEN Holdings Co., Ltd., Kyoto (JP)

(72) Inventors: Junta MIYAMOTO, Kyoto-shi (JP); Moritaka YANO, Kyoto-shi (JP); Tsuyoshi MITSUHASHI, Kyoto-shi (JP); Yasuhiro SHIBA, Kyoto-shi (JP)

(21) Appl. No.: 15/399,229

(22) Filed: Jan. 5, 2017

(30) Foreign Application Priority Data
Feb. 19, 2016 (JP) 2016-029810

(51) Int. Cl. C23C 16/458; C23C 16/455

(52) U.S. Cl. CPC C23C 16/458; C23C 16/455

(57) ABSTRACT

A controller causes treatment of a substrate with a treating gas by operating an exhaust portion to discharge gas from a treatment space and supplying the treating gas from a treating gas generator to the treatment space. After supplying a dry gas at a treatment flow rate to the treatment space and replacing the gas with the dry gas, the controller carries out a slow leak operation to flow the dry gas from a dry gas supplier in a predetermined direction and to supply the dry gas to a filter in a lower flow rate than the treatment flow rate.

### BACKGROUND OF THE INVENTION

(1) Field of the Invention

This invention relates to a substrate treating apparatus and a substrate treating method for performing a predetermined treatment of, by supplying a treating gas to, semiconductor wafers, substrates for liquid crystal displays, substrates for plasma displays, substrates for organic ELs, substrates for FEDs (Field Emission Displays), substrates for optical displays, substrates for magnetic disks, substrates for magneto-optical disks, substrates for photomasks and substrates for solar cells (hereinafter called simply the substrates),

(2) Description of the Related Art

Conventionally, this type of apparatus includes one which, before forming resist film on a substrate surface by supplying a resist solution thereto, performs hydrophobizing treatment of the substrate by supplying thereto a treating gas including HMDS (hexamethyldisilazane) gas to improve adhesion of the resist film formed on the substrate (see Japanese patent No. 3425826, for example).

Here, a specific construction of a conventional example will be described with reference to FIG. 1. FIG. 1 is a schematic view showing a principal portion of a substrate treating apparatus according to the conventional example.

The substrate treating apparatus according to the conventional example includes a support table 101 for supporting a wafer W, a lid 103 for covering an upper surface of the support table 101, and a gas supply section 105 for supplying a treating gas from a central part of the lid 103 in plan view to the interior of the lid 103. The gas supply section 105 has a bubbling tank 107 for generating HMDS gas, a pipe 109 for supplying the HMDS gas from inside the bubbling tank 107, a pipe 111 for supplying nitrogen (N₂) gas as carrier gas or replacement gas, a pipe joint 113 for connecting these pipes 109 and 111, a supply pipe 115 connected to provide a communication between the pipe joint 113 and the lid 103, and a filter 117 mounted on the supply pipe 115 for removing particles from the gas flowing through the supply pipe 115.

In the substrate treating apparatus constructed in this way, hydrophobizing treatment is carried out on the wafer W as follows, for example. First, the wafer W is brought in and placed on the support table 101, and the wafer W is covered with the lid 103. And the treating gas is supplied from the supply pipe 115 to the interior of the lid 103. After the treating gas is supplied for a predetermined supply time, the supply of the treating gas is stopped and this state is maintained for a predetermined time to expose the wafer W to a treatment atmosphere inside the lid 103. Then, the nitrogen gas is supplied from the pipe 111 for replacing the treatment atmosphere, and the lid 103 is moved to take out the wafer W.

The conventional example with such construction has the following problem.

With the conventional apparatus, it is general practice to periodically perform maintenance for cleaning the lid 103 by removing the supply pipe 115 from the pipe joint 113, for example. However, there occurs a problem in treatment after the maintenance that particles may adhere especially to a central part of the wafer W in plan view.

### SUMMARY OF THE INVENTION

This invention has been made having regard to the state of the art noted above, and its object is to provide a substrate treating apparatus and a substrate treating method which can prevent adhesion of particles to substrates even in treatment after maintenance.

To fulfill the above object, Inventors herein have made intensive research and attained the following findings. Incidentally, the phenomenon described above did not occur immediately after a dummy dispense in which the treating gas was supplied only for a definite period of time in a state where no wafer W was placed, but the phenomenon occurred again after a while. As a result of analyzing the particles adhering to the wafers W with a scanning electron microscope (SEM), it was found that their components included silicon (Si), oxygen (O), carbon (C), fluorine (F) and some metals. The particles adhering to the wafers W were sized larger than those which should have been captured for being unable to pass through the membrane of the filter 117. From these facts, Inventors thought that the problem occurred due to the following mechanism.

Reference is made here to FIGS. 2A-2C. FIGS. 2A-2C are schematic views showing the mechanism of problem occurrence. When hydrophobizing treatment is given to a wafer W, as shown in FIG. 2A, various types of particles PM included in the treating gas are captured by the filter 117, and the HMDS gas condenses and adheres as a liquid of HMDS to the filter 117. When the supply pipe 115 is removed from the pipe joint 113 at the time of maintenance, the filter 117 will be exposed to air. Then, as shown in FIG. 2B, the moisture in the air and the liquid of HMDS react to produce alkaline substances such as ammonium ion (NH4⁺) and trimethylsilyl group (TMS). These alkaline substances react with the various types of particles PM to dissolve the various types of particles PM and produce gelatinous particles GPM. These gelatinous particles GPM can pass through the membrane of the filter 117. Therefore, when the treating gas is supplied after the maintenance, as shown in FIG. 2C, part of the gelatinous particles GPM separate from, or all of them penetrate, the membrane of the filter 117, which are carried by the flow of the treating gas to adhere to the central part of the wafer W in plan view. Based on such findings, this invention provides the following construction.

To fulfill the above object, this invention provides the following construction.

A substrate treating apparatus for treating a substrate with a treating gas, according to this invention, comprises a treating section including a support table for supporting the substrate, and a lid member for covering the substrate placed on the support table and forming a treatment space during treatment of the substrate; an exhaust portion for discharging gas in the treatment space; a treating gas generator for generating the treating gas by vaporizing a treating solution; a dry gas supplier for supplying a dry gas; a supply pipe having one end thereof connected to the lid member for supplying the treating gas and the dry gas to the treatment space; a filter for removing particles included in the treating gas supplied to the treatment space by flowing the treating gas from the gas generator in a predetermined direction; and a controller for treating the substrate in the treating section with the treating gas by operating the exhaust portion to discharge the gas from the treatment space and supplying the treating gas from the treating gas generator to the treatment space, and after supplying the dry gas at a treatment flow rate to the treatment space to replace the treating gas in the treatment space with the dry gas, for carrying out a slow leak operation to flow the dry gas from the dry gas supplier in the predetermined direction and to supply the dry gas to the filter in a lower flow rate than the treatment flow rate.

According to this invention, the controller treats the substrate in the treating section with the treating gas by operating the exhaust portion to discharge the gas from the treatment space and supplying the treating gas to the treatment space. Next, the controller supplies the dry gas at the treatment flow rate to the treatment space to replace the treating gas in the treatment space with the dry gas. Subsequently, the controller carries out a slow leak operation to flow the dry gas in the predetermined direction and to supply the dry gas to the filter in a lower flow rate than the treatment flow rate. Thus, even when the supply pipe is removed for maintenance after completion of the treatment of the substrate, air containing moisture is prevented from contacting the filter. As a result, gelling of particles due to the reaction of the treating gas and moisture can be prevented, and thus the particles are prevented from passing through the filter due to the gelling. Even in treatment after the maintenance, the particles are prevented from adhering to the substrate.

In this invention, it is preferred that the substrate treating apparatus comprises an upstream supply pipe for receiving the treating gas from the treating gas generator and the dry gas from the dry gas supplier; a pipe joint to which the other end of the supply pipe is removably connected and one end of the upstream supply pipe is removably connected; a first switch valve provided at the other end of the upstream supply pipe for controlling flow of the treating gas from the treating gas generator to the upstream supply pipe; and a second switch valve for controlling flow of the dry gas from the dry gas supplier to the upstream supply pipe; wherein the filter is mounted on the upstream supply pipe.

Since the filter is provided on the upstream supply pipe, the particles included in the treating gas and dry gas can be removed. Further, since the particles produced in the first switch valve and second switch valve are also removable by the filter, the substrate can be treated cleanly.

In this invention, it is preferred that the substrate treating apparatus comprises slow leak piping connected to positions upstream and downstream of the second switch valve; and a control valve for controlling a flow rate of the dry gas flowing through the slow leak piping; wherein the controller is arranged to operate the control valve to carry out the slow leak operation.

With the slow leak piping and control valve constituting a construction exclusive for the slow leak operation, the slow leak operation is flexibly controllable compared with the case where the slow leak operation is directly carried out using the dry gas supply source.

In this invention, it is preferred that the first switch valve and the second switch valve are in form of a three-way valve.

With the three-way valve which can selectively switch between two fluids, the construction can be simplified and cost can be held down.

In this invention, it is preferred that the controller is arranged to carry out the slow leak operation at a point of time when the lid member begins to separate from the support table after the above-noted replacement.

At a time point of time when the lid member begins to move up from the support table, there arises a possibility that ambient air containing moisture flows in. However, the slow leak operation started at this time will prevent the reaction of moisture and treating gas occurring in the filter.

In this invention, it is preferred that the controller is arranged to cause the substrate to be placed on the support table for the treatment and to stop the slow leak operation at a point of time when the lid member contacts the support table.

There is no longer the possibility that air containing moisture flows in at the point of time when the lid member contacts the support table. By stopping the slow leak operation at this time, a wasteful consumption of the dry gas can be inhibited.

In another aspect of this invention, a substrate treating method is provided for treating a substrate with a treating gas, using a treating section including a support table for supporting the substrate, and a lid member for covering the substrate placed on the support table and forming a treatment space. The method comprises a treating step for treating the substrate with the treating gas in the treating space by discharging gas from the treatment space and supplying to the treatment space the treating gas formed of a vaporized treating solution and flowing in a predetermined direction through a filter to remove particles from the treating gas; a replacing step for supplying a dry gas at a treatment flow rate to the treatment space and replacing the treating gas in the treatment space with the dry gas; and a slow leak operation step for flowing the dry gas in the predetermined direction and supplying the dry gas to the filter in a lower flow rate than the treatment flow rate.

According to this invention, the treating step is executed to treat the substrate in the treating section with the treating gas by discharging the gas from the treatment space and supplying the treating gas to the treatment space. Next, the replacing step is executed to supply the dry gas at the treatment flow rate to the treatment space to replace the treating gas in the treatment space with the dry gas. The slow leak operation step is executed to flow the dry gas in the predetermined direction and to supply the dry gas to the filter in a lower flow rate than the treatment flow rate. Thus, when maintenance is carried out after completion of the treatment of the substrate, air containing moisture is prevented from contacting the filter. As a result, gelling of particles due to the reaction of the treating gas and moisture can be prevented, and thus the particles are prevented from passing through the filter due to the gelling. Even in treatment after the maintenance, the particles are prevented from adhering to the substrate.

In this invention, it is preferred that the slow leak operation step is executed at a point of time when the lid member begins to separate from the support table after the replacing step.

At a time point of time when the lid member begins to move up from the support table, there arises a possibility that ambient air containing moisture flows in. However, the slow leak operation started at this time will prevent the reaction of moisture and treating gas occurring in the filter.

In this invention, it is preferred that the slow leak operation step is executed to cause the substrate to be placed on the support table for the treating step, the slow leak operation step being stopped at a point of time when the lid member contacts the support table.

There is no longer the possibility that air containing moisture flows in at the point of time when the lid member contacts the support table. By stopping the slow leak operation at this time, a wasteful consumption of the dry gas can be inhibited.

### BRIEF DESCRIPTION OF THE DRAWINGS

For the purpose of illustrating the invention, there are shown in the drawings several forms which are presently preferred, it being understood, however, that the invention is not limited to the precise arrangement and instrumentalities shown.

FIG. 1 is a schematic view showing a principal part of a substrate treating apparatus according to a conventional example;

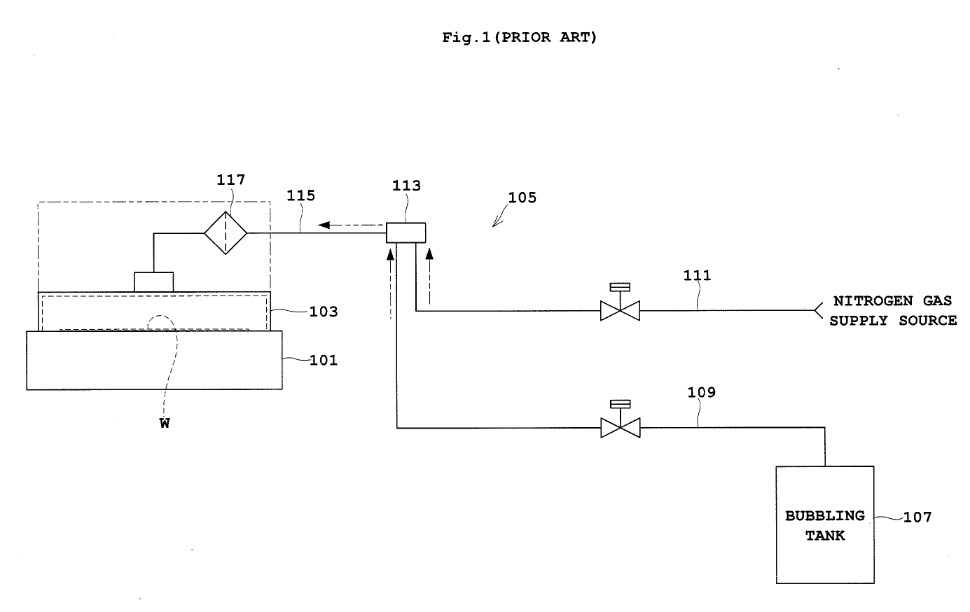

FIGS. 2A-2C are schematic views showing a mechanism of problem occurrence;

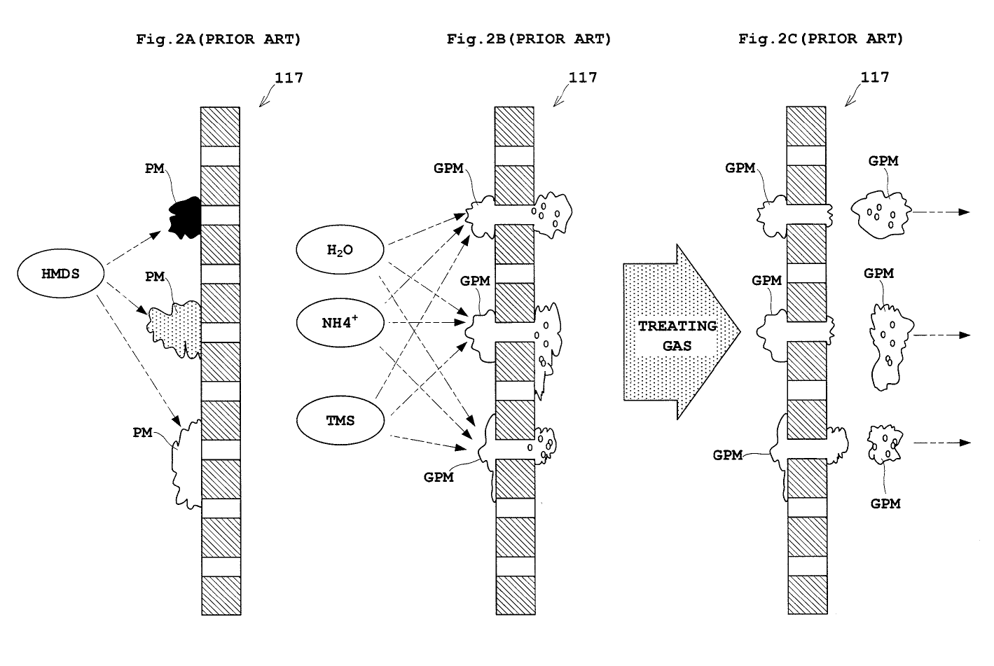

FIG. 3 is an overall view showing an outline of a substrate treating apparatus according to this invention;

FIG. 4 is a time chart showing operations of various components and pressure variations in a treatment space; and

FIG. 5 is an overall view showing an outline of a substrate treating apparatus according to a modification.

### DESCRIPTION OF THE PREFERRED EMBODIMENTS

A preferred embodiment of this invention will be described in detail hereinafter with reference to the drawings.

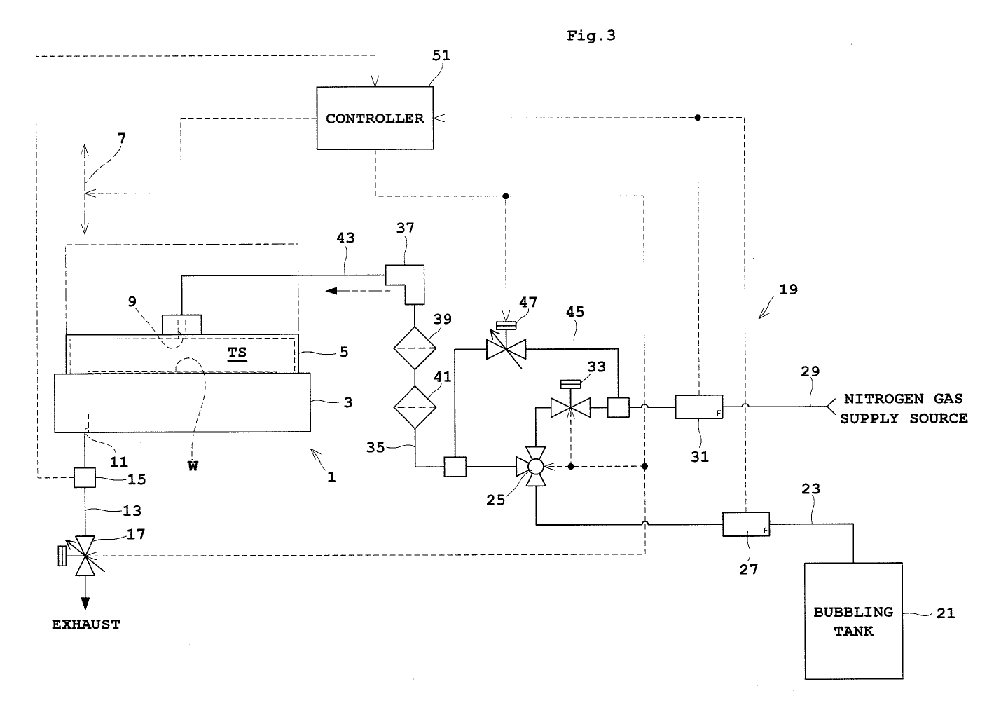

FIG. 3 is an overall view showing an outline of a substrate treating apparatus according to this invention.

The substrate treating apparatus according to this invention performs treatment of wafers W with a treating gas. Specifically, treatment is carried out with a treating gas including a gas resulting from gasification of a treating liquid. The treating liquid is HMDS (hexamethyldisilazane), for example. This HMDS has a property to act on the surface of a wafer W and reform the surface of the wafer W to a hydrophobic surface.

A treating section 1 for treating the wafer W includes a support table 3 and a lid member 5. The support table 3 has a larger outside dimension than am outside diameter of the wafer W in plan view. The lid member 5 has a space of larger inside diameter than an outer shape of the wafer W in plan view. This lid member 5 is constructed vertically movable relative to an upper surface of the support table 3 by a lift mechanism 7. At the time of treatment of the wafer W, the lid member 5 covers the wafer W placed on the support table 3 and forms a treatment space TS inside. The lift mechanism 7 vertically moves the lid member 5 between a “transfer position” spaced upward from the support table 3 and a “treating position” with a lower edge of the lid member 5 contacting the upper surface of the support table 3. The lid member 5 has a supply port 9 formed in a central part thereof in plan view so that the treating gas may spread evenly all over the wafer W.

The support table 3 has embedded therein a heater (not shown) for heating the wafer W placed on the upper surface thereof, and support pins (not shown) vertically movable when transferring the wafer W and for contacting the lower surface of the wafer W to support the wafer W. The support table 3 has an exhaust port 11 formed therein and communicating with the treatment space TS. One end of an exhaust pipe 13 is connected to this exhaust port 11. The other end of the exhaust pipe 13 is connected to exhaust devices such as an exhaust utility and an exhaust pump (not shown). The exhaust pipe 13 has a pressure sensor 15 and a control valve 17 mounted thereon. The control valve 17 can adjust flow rate and, when the lid member 5 is in the treating position, is used to perform a sealing action by increasing an exhaust volume to suck the lid member 5 into contact with the upper surface of the support table 3, and to replace the gas in the treatment space TS. The pressure sensor 15 detects an internal pressure of the treatment space TS.

The above exhaust port 11 corresponds to the “exhaust portion” in this invention.

The treating section 1 is supplied with gas from a supply system 19. The supply system 19 supplies the treating section 1 with the treating gas including HMDS gas, and dry nitrogen gas (dry N₂ gas) as inert gas.

One end of piping 23 is connected to a bubbling tank 21 for producing the treating gas including HMDS gas, and the other end of the piping 23 is connected to a first input port of a three-way valve 25. The piping 23 has a flowmeter 27 mounted thereon for monitoring a flow rate of the treating gas. Piping 29 has one end thereof connected to a dry nitrogen gas supply source, and the other end connected to a second input port of the three-way valve 25. The piping 29 has mounted thereon a flowmeter 31 for monitoring a flow rate of the dry nitrogen gas, and a switch valve 33 for controlling flow of the dry nitrogen gas to the second input port of the three-way valve 25.

The above bubbling tank 21 corresponds to the “treating gas generator” in this invention. The piping 29 corresponds to the “dry gas supplier” in this invention. The three-way valve 25 corresponds to the “first switch valve” and the “second switch valve” in this invention.

Piping 35 is disposed downstream of the three-way valve 25. One end of this piping 35 is removably connected to a pipe joint 37, and the other end thereof is connected to an output port of the three-way valve 25. The piping 35 has a filter 39 and a filter 41 arranged in series thereon. The filter 39 and filter 41 are filters of the same specification, but the upstream filter 41 may be coarser in the specification than the downstream filter 39, for example.

Since the filters 39 and 41 are arranged in series on the piping 35, the particles included in HMDS gas and dry nitrogen gas can be removed reliably. Further, since particles produced by opening and closing operations of the three-way valve 25 can also be removed by the filters 39 and 41, the wafer W can be treated cleanly. Further, since the three-way valve 25 carries out switching between dry nitrogen gas and HMDS gas, the construction can be simplified.

The above piping 35 corresponds to the “upstream supply pipe” in this invention.

One end of a supply pipe 43 is connected to the supply port 9 of the lid member 5. The other end of the supply pipe 43 is removably connected to the pipe joint 37. With the substrate treating apparatus according to this embodiment, a maintenance operation for removing dirt and the like adhering to the lid member 5 is carried out in a state of the other end of the supply pipe 43 removed from the pipe joint 37.

The piping 29 described hereinbefore has a position thereof upstream of the switch valve 33 and a position downstream of the three-way valve 25 and upstream of the filters 39 and 41 connected to be in communication with each other through slow leak piping 45. This slow leak piping 45 has a control valve 47 mounted thereon. This control valve 47 adjusts the flow rate of dry nitrogen gas. This control valve 47 has a flow rate at an open time that can be set beforehand. This flow rate at the open time is set less than a treatment flow rate at the time of replacement by the dry nitrogen gas described hereinafter.

Thus, with the slow leak piping 45 and control valve 47 constituting a construction exclusive for slow leak operation, the slow leak operation is flexibly controllable compared with the case where the slow leak operation is directly carried out using the dry nitrogen gas supply source.

A controller 51 is formed of a CPU and memory. The memory, not shown, stores beforehand a recipe specifying a procedure for treating wafers W. The controller 51 can control up-and-down movement operation of the lift mechanism 7, opening and closing operation of the control valve 17, switching operation of the three-way valve 25, opening and closing operation of the switch valve 33 and opening and closing operation of the control valve 47, and monitors the pressure sensor 15 and flowmeters 27 and 31. The controller 51 operates the above components based on the recipe, and controls operation of the substrate treating apparatus.

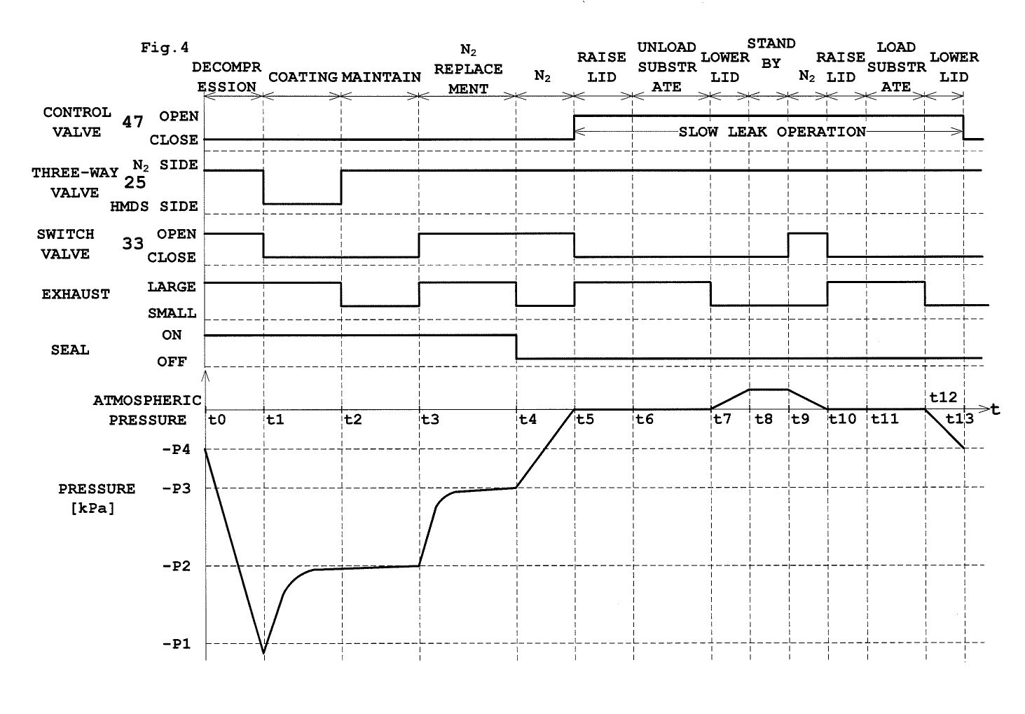

Next, operation of the substrate treating apparatus having the above construction will be described with reference to FIG. 4. FIG. 4 is a time chart showing operation of each component and pressure variations in the treatment space.

Here, a state where a wafer W which is an object of treatment has been placed on the support table 3 and the lid member 5 has been moved to the treating position in contact with the support table 3 is set to time t0 on the time chart. At this time t0, the control valve 17 is set to a high flow rate, the lid member 5 is pressed on the support table 3 to provide a seal-on state, the switch valve 33 is opened, the three-way valve 25 is set to the dry nitrogen gas side, and the control valve 47 is closed. At this time t0, the pressure in the treatment space TS is assumed to be -P4 [kPa].

The controller 51 operates the control valve 17 to discharge exhaust gas from the exhaust port 11 so that the pressure in the treatment space TS become -P1 [kPa] or below at time t1 (“decompression” in the upper part of FIG. 4). Consequently, the wafer W is placed in a decompressed treatment atmosphere. The controller 51, upon confirmation made based on the signal from pressure sensor 15 at time t1 that the pressure in the treatment space TS has become -P1 [kPa] or below, switches the three-way valve 25 to the HMDS gas side, and closes the switch valve 33 (“coating” in the upper part of FIG. 4). This state is maintained until time t2. Consequently, the wafer W is exposed to HMDS gas atmosphere, and hydrophobization progresses over the entire surface of the wafer W. At this time, the supply of HMDS gas gradually raises the pressure in the treatment space TS to the vicinity of -P2 [kPa] at time t2.

Next, the controller 51, at time t2, switches the three-way valve 25 to the dry nitrogen gas side, and operates the control valve 17 to set the exhaust gas from the exhaust port 11 to a low flow rate (“maintain” in the upper part of FIG. 4). Consequently, the treatment atmosphere of HMDS gas in the treatment space TS is maintained until time t3. Since the switch valve 33 remains closed although the three-way valve 25 is switched to the dry nitrogen gas side, the dry nitrogen gas is not supplied to the treatment space TS.

The controller 51, at time t3, opens the switch valve 33 and operates the control valve 17 to discharge the gas from the exhaust port 11 at a high flow rate (“N₂ replacement” in the upper part of FIG. 4). Consequently, the dry nitrogen gas is supplied at the treatment flow rate into the treatment space TS. However, the ratio of flow rate between the drying nitrogen gas and the exhaust gas is set and the sealing of the lid member 5 and support table 3 is maintained in ON state, so that the pressure in the treatment space TS balance at negative pressure (-P3 [kPa]) at time t4.

The period of time from time t0 to time t3 described above corresponds to the “treating step” in this invention. The controller 51, at time t4, operates the control valve 17 to set the gas exhaust from the exhaust port 11 to a low flow rate (“N₂” in the upper part of FIG. 4). Consequently, combined with supply of the dry nitrogen gas, the pressure in the treatment space TS returns to atmospheric pressure at time t5, and the sealing of the lid member 5 and support table 3 is turned off.

The period from time t3 to time t4 described above corresponds to the “replacing step” in this invention.

The controller 51, at time t5, operates the lift mechanism 7 to raise the lid member 5 from the support table 3 to the transfer position, and operates the control valve 17 to set the gas exhaust from the exhaust port 11 to a high flow rate (“raise lid” in the upper part of FIG. 4). Further, the controller 51, when the lower edge of the lid member 5 begins to separate from the upper surface of the support table 3 at time t5, closes the switch valve 33 and opens the control valve 47. Consequently, the dry nitrogen gas is supplied into the piping 35 at a lower flow rate than the treatment flow rate (“slow leak operation” in the upper part of FIG. 4).

Next, the controller 51 causes a transport mechanism not shown to unload the hydrophobized wafer W from the treating section 1 during a period from time t6 to time t7 (“unload substrate” in the upper part of FIG. 4).

The controller 51, at time t7, operates the control valve 17 to set the gas exhaust from the exhaust port 11 to the low flow rate, and operates the lift mechanism 7 to lower the lid member 5 to the treating position (“lower lid” in the upper part of FIG. 4). Then, the controller 51 maintains this state until time t9 (“standby” in the upper part of FIG. 4). During the period from this time t7 to time t10, the pressure in the treatment space TS temporarily becomes positive because the exhaust gas from the exhaust port 11 is reduced.

The controller 51, at time t9, opens the switch valve 33 to supply the treatment space TS with a treatment flow volume part added to the dry nitrogen gas at the low flow rate in the slow leak operation (“N₂” in the upper part of FIG. 4). Consequently, the interior of the treatment space TS is maintained in an inert gas atmosphere.

The controller 51, at time t10, for treatment of a next wafer W, operates the lift mechanism 7 to raise the lid member 5 to the transfer position, and operates the control valve 17 to set the gas exhaust from the exhaust port 11 to a high flow rate (“raise lid” in the upper part of FIG. 4).

The controller 51 places the next wafer W on the support table 3 at time t11 (“load substrate” in the upper part of FIG. 4). Subsequently, the controller 51, at time t12, operates the lift mechanism 7 to lower the lid member 5 to the treating position, and operates the control valve 17 to set the gas exhaust from the exhaust port 11 to the low flow rate (“lower lid” in the upper part of FIG. 4). The controller 51, at time t13 when the lid member 5 has moved to the treating position, closes the control valve 47 to terminate the slow leak operation.

The substrate treating apparatus in this embodiment performs treatment as described above. At this time, the slow leak operation is carried out from time t5 to time t13 (corresponding to the “slow leak operation step” in this invention). When, for example, maintenance for cleaning the lid member 3 is carried out in the standby state from time t8 to time t9, the other end of the supply pipe 43 may be removed from the pipe joint 37 to clean the lid member 3 and supply pipe 43. In such a case, air can be prevented from entering the filters 39 and 41 from the piping 35. It is therefore possible to prevent moisture in the air from contacting the filters 39 and 41. As a result, gelling of particles due to the reaction of HMDS gas and moisture can be prevented, and thus the particles are prevented from passing through the filters 39 and 41 due to the gelling. Even in treatment after the maintenance, the particles are prevented from adhering to the wafer W.

At time t5 when the lid member 5 begins to move up from the support table 3, there arises a possibility that air containing moisture flows into the treatment space TS from around the lid member 5. However, the slow leak operation started at this time t5 will prevent the reaction of moisture and treating gas occurring in the filters.

Further, there is no longer the possibility that air containing moisture flows into the treatment space TS at time t13 when the lid member 5 contacts the support table 3. By stopping the slow leak operation at this time t13, a wasteful consumption of dry nitrogen gas can be inhibited.

This invention is not limited to the foregoing embodiment, but may be modified as follows:

(1) The foregoing embodiment has been described taking HMDS gas as an example of treating gas. This invention is not limited to such treating gas. For example, the invention is applicable also to treating gases of silylation agents such as TMSDMA (N-trimethyl silyldimethylamine) and TMSDEA (N-trimethyl silyldiethylamine).

(2) In the foregoing embodiment, dry nitrogen gas has exemplified the dry gas, but this invention is not limited to such a gas. For example, an inert gas such as argon or helium may be employed.

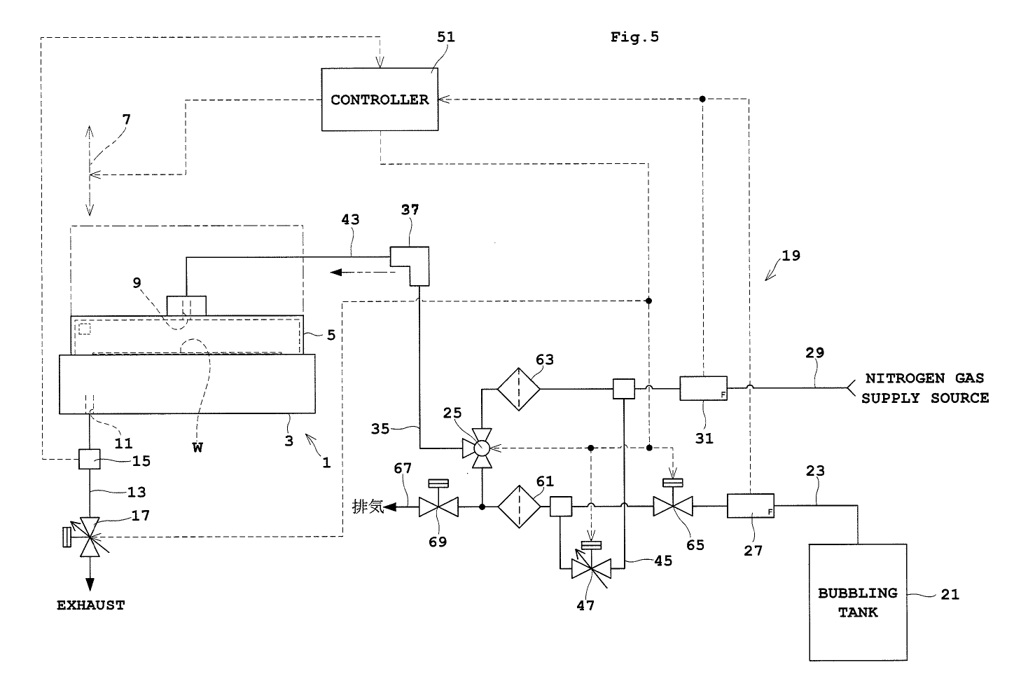

(3) In the foregoing embodiment, the piping 35 has two filters, i.e. the filters 39 and 41, arranged in series thereon. The number of filters may be reduced to one, or filters may be arranged in positions shown in FIG. 5. FIG. 5 is an overall view showing an outline of a substrate treating apparatus according to a modification.

In this modification, the filters 39 and 41 are not provided on the piping 35, but a filter 61 is provided on the piping 23 and a filter 63 on the piping 29. And one end of the slow leak piping 45 is connected to the piping 29, while the other end of the slow leak piping 45 is connected to the piping 23 upstream of the filter 61. The control valve 47 remains on the slow leak piping 45. A switch valve 65 is mounted on the piping 23 upstream of the filter 61. A leak exhaust pipe 67 is branched from a position downstream of the filter 61 and upstream of the three-way valve 25. A leak exhaust valve 69 is mounted on the leak exhaust pipe 67. And the switch valve 65 is closed to stop HMDS gas, the leak exhaust valve 69 is opened, and further the control valve 47 is opened. Consequently, a slow leak operation can be performed for the filter 61 to produce the same effect as in the foregoing embodiment. Moreover, this modification can produce the same effect also when such maintenance is carried out as for changing the three-way valve 25.

(4) In the foregoing embodiment, the filters 39 and 41 are provided on the piping 35, but the filters 39 and 41 may be provided on the supply pipe 43. In this case, however, the supply pipe 43 is constructed attachable to and detachable from the lid member 5.

(5) In the foregoing embodiment, the three-way valve 23 is provided to switch between the two types of gas, but this switching may be made by using two separate switch valves.

(6) In the foregoing embodiment, dry nitrogen gas is used as displacement gas. This invention is applicable also to the case where dry nitrogen gas is used as carrier gas such that dry nitrogen gas is mixed with HMDS gas to make a treating gas.

This invention may be embodied in other specific forms without departing from the spirit or essential attributes thereof and, accordingly, reference should be made to the appended claims, rather than to the foregoing specification, as indicating the scope of the invention.

What is claimed is:

1. A substrate treating apparatus for treating a substrate with a treating gas, comprising:
a treating section including a support table for supporting the substrate, and a lid member for covering the substrate placed on the support table and forming a treatment space during treatment of the substrate;
an exhaust portion for discharging gas in the treatment space;
a treating gas generator for generating the treating gas by vaporizing a treating solution;
a dry gas supplier for supplying a dry gas;
a supply pipe having one end thereof connected to the lid member for supplying the treating gas and the dry gas to the treatment space;
a filter for removing particles included in the treating gas supplied to the treatment space by flowing the treating gas from the gas generator in a predetermined direction; and
a controller for treating the substrate in the treating section with the treating gas by operating the exhaust portion to discharge the gas from the treatment space and supplying the treating gas from the treating gas generator to the treatment space, and after supplying the dry gas at a treatment flow rate to the treatment space to replace the treating gas in the treatment space with the dry gas, for carrying out a slow leak operation to flow the dry gas from the dry gas supplier in the predetermined direction and to supply the dry gas to the filter in a lower flow rate than the treatment flow rate.

2. The substrate treating apparatus according to claim 1, comprising:
an upstream supply pipe for receiving the treating gas from the treating gas generator and the dry gas from the dry gas supplier;
a pipe joint to which the other end of the supply pipe is removably connected and one end of the upstream supply pipe is removably connected;
a first switch valve provided at the other end of the upstream supply pipe for controlling flow of the treating gas from the treating gas generator to the upstream supply pipe; and
a second switch valve for controlling flow of the dry gas from the dry gas supplier to the upstream supply pipe;
wherein the filter is mounted on the upstream supply pipe.

3. The substrate treating apparatus according to claim 2, comprising:
slow leak piping connected to positions upstream and downstream of the second switch valve; and
a control valve for controlling a flow rate of the dry gas flowing through the slow leak piping;
wherein the controller is arranged to operate the control valve to carry out the slow leak operation.

4. The substrate treating apparatus according to claim 2, wherein the first switch valve and the second switch valve are in form of a three-way valve.

5. The substrate treating apparatus according to claim 3, wherein the first switch valve and the second switch valve are in form of a three-way valve.

6. The substrate treating apparatus according to claim 1, wherein the controller is arranged to carry out the slow leak operation at a point of time when the lid member begins to separate from the support table after the replacement.

7. The substrate treating apparatus according to claim 2, wherein the controller is arranged to carry out the slow leak operation at a point of time when the lid member begins to separate from the support table after the replacement.

8. The substrate treating apparatus according to claim 3, wherein the controller is arranged to carry out the slow leak operation at a point of time when the lid member begins to separate from the support table after the replacement.

9. The substrate treating apparatus according to claim 4, wherein the controller is arranged to carry out the slow leak operation at a point of time when the lid member begins to separate from the support table after the replacement.

10. The substrate treating apparatus according to claim 5, wherein the controller is arranged to carry out the slow leak operation at a point of time when the lid member begins to separate from the support table after the replacement.

11. The substrate treating apparatus according to claim 1, wherein the controller is arranged to cause the substrate to be placed on the support table for the treatment and to stop the slow leak operation at a point of time when the lid member contacts the support table.

12. The substrate treating apparatus according to claim 2, wherein the controller is arranged to cause the substrate to be placed on the support table for the treatment and to stop the slow leak operation at a point of time when the lid member contacts the support table.

13. The substrate treating apparatus according to claim 3, wherein the controller is arranged to cause the substrate to be placed on the support table for the treatment and to stop the slow leak operation at a point of time when the lid member contacts the support table.

14. The substrate treating apparatus according to claim 4, wherein the controller is arranged to cause the substrate to be placed on the support table for the treatment and to stop the slow leak operation at a point of time when the lid member contacts the support table.

15. The substrate treating apparatus according to claim 5, wherein the controller is arranged to cause the substrate to be placed on the support table for the treatment and to stop the slow leak operation at a point of time when the lid member contacts the support table.

16. The substrate treating apparatus according to claim 6, wherein the controller is arranged to cause the substrate to be placed on the support table for the treatment and to stop the slow leak operation at a point of time when the lid member contacts the support table.

17. A substrate treating method for treating a substrate with a treating gas, using a treating section including a support table for supporting the substrate, and a lid member for covering the substrate placed on the support table and forming a treatment space, the method comprising:
a treating step for treating the substrate with the treating gas in the treating space by discharging gas from the treatment space and supplying to the treatment space the treating gas formed of a vaporized treating solution and flowing in a predetermined direction through a filter to remove particles from the treating gas;
a replacing step for supplying a dry gas at a treatment flow rate to the treatment space and replacing the treating gas in the treatment space with the dry gas; and
a slow leak operation step for flowing the dry gas in the predetermined direction and supplying the dry gas to the filter in a lower flow rate than the treatment flow rate.

18. The substrate treating method according to claim 17, wherein the slow leak operation step is executed at a point of time when the lid member begins to separate from the support table after the replacing step.

19. The substrate treating method according to claim 17, wherein the slow leak operation step is executed to cause the substrate to be placed on the support table for the treating step, the slow leak operation step being stopped at a point of time when the lid member contacts the support table.

20. The substrate treating method according to claim 18, wherein the slow leak operation step is executed to cause the substrate to be placed on the support table for the treating step, the slow leak operation step being stopped at a point of time when the lid member contacts the support table.
